(19) United States
(12) Patent Application Publication
(10) Pub. No.: US 2012/0305056 A1
(43) Pub. Date: Dec. 6, 2012

(54) SOLAR CELL MODULE

(75) Inventors: Henning NAGEL, Alzenau (DE); Ralf Gueldner, Aschaffenburg (DE)

(73) Assignee: SCHOTT SOLAR AG, Mainz (DE)

(21) Appl. No.: 13/485,498

(22) Filed: May 31, 2012

(30) Foreign Application Priority Data
May 31, 2011 (DE) 10 2011 050 776.0
Aug. 25, 2011 (DE) 10 2011 052 992.6

(51) Int. Cl. H01L 31/048

(52) U.S. Cl. 136/251

(57) ABSTRACT

The invention relates to a solar cell module comprising electrically interconnected solar cells with front and backs, a transparent first layer running along the front sides, which is covered on the front laterally by a transparent cover, as well as a second layer running along the backsides, which is covered at the back by a second cover. In order to prevent and/or minimize a potential-induced reduction to a large extent and/or obtain an improved stability vis-à-vis thermo-cycling, it is suggested that first layer consists of a first polymer material and the second layer consists of a second polymer material deviating from the first polymer material and the fact that specific resistance is larger p₁ of the first material is greater than specific resistance p2 of the second material.

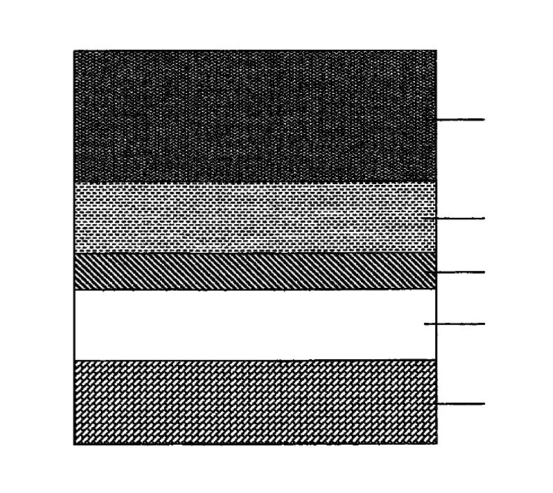

### CROSS-REFERENCE TO RELATED APPLICATIONS

This application is related to, and claims priority in, German Patent Application No. 10 2011 050 776.0 filed on May 31, 2011 and German Patent Application No. 10 2011 052 992.6 filed on Aug. 25, 2011, the disclosures of which are incorporated in its entirety by reference herein.

### FIELD OF THE DISCLOSURE

The invention relates to a solar cell module comprising
electrically interconnected solar cells with front and backs,
a transparent coating running along the front sides, whereby the front-side is covered by transparent first cover, as well as
a second coating running along the back side, which is covered on the back side by a second cover.

### BACKGROUND OF THE DISCLOSURE

In order to provide suitable voltage and output with solar cells, whereby the radiation is converted into electricity, the interconnection of solar cells to larger units, the so-called modules, is known.

For the production of suitable solar cell modules, a transparent plastic film of ethyl vinyl acetate or silicone rubber can be applied on a glass disk e.g. of soda lime glass forming a first cover, on which the interconnected solar cells are then positioned. Here, it can concern crystalline solar cells, which are connected in series by means of links or in parallel. Then, a second plastic film is applied along the rear side of the solar cells, which according to the State of the Art consists of the same material as the front-side running plastic film.

Then, from polyvinyl fluoride (Tedlar) and polyester a rear-side of the second cover is applied. Subsequently, lamination of the module takes place either in vacuum preferably in the temperature range of 120° C. to 160° C. or in autoclaves with excess pressure in the same temperature range. In this lamination process, a three-dimensional cross-linked and no longer melting plastic film forms from the EVA-foils, into which cells embed and these are connected firmly with the front-side cover, thus the glass disk, and the rear cover.

Suitable solar cell modules show certain instabilities in relation to high temperatures, load variations at temperature and dampness effects. A potential-induced degradation can also be determined.

US-A-2010/0139740 describes a solar cell module, whose solar cells are covered by an embedding material, in particular of polyethyl vinyl acetate. An insulating layer runs along the front-side running embedding material, which consists of a fluorine containing polymer. The insulating layer for its part can be covered by another embedding material layer or directly by a glass disk.

The object of the U.S. Pat. No. 5,476,553 is a solar cell module, whose solar cells are covered front- and back-side by layers, which can consist of an ionomer.

U.S. Pat. No. 5,648,325 discloses a solar cell, the front and backs are covered by a transparent layer.

WO-A-2010/054274 relates to a solar cell panel, which is covered by sealing compound on the front- and rear-side, which for its part is covered by a front glass and/or a rear-side layer.

### SUMMARY OF THE DISCLOSURE

The object of the present invention is to prevent considerably or minimize in particular a potential-induced degradation and an improved stability in relation to load variations due to temperature. The penetration of moisture should not have any noticeable effect on the electrical output of the module.

Said object is proposed to be achieved by the fact that the first layer consists of a first polymer material and the second layer consists of a second polymer material deviating from the first polymer material, whereby the specific resistance ρ₁ of the first material is greater than the specific resistance ρ₂ of the second material, and that the material properties of the first and second layer differ in that the storage module G₁ of the first layer is greater than the storage module G₂ of the second layer.

Surprisingly, it is shown that, if the front-side, thus the embedding material turned towards the radiation deviates from the rear side, synergic effect results between the physical and chemical characteristics of the embedding materials with the consequence that in particular the potential-induced degradation is reduced.

Thus, a solar module can be presented, which compared to known structures has high electrical output with simultaneously improved stability in relation to high temperatures, load variations at temperature and dampness effect.

In particular, it is proposed that the first polymer material is a thermoplastic material, in particular at least a material from the group of ionomer, polymethyl metacrylate, PP, Polycarbonate, polyethylene terephthalate, polyolefin with ionic and covalent bonds, polyvinyl butyral, thermoplastic polyurethane, polypropylene, polyethylene, polystyrene, siloxane or co-polymers of these.

The invention is characterized also by the fact that the second polymer material consists of a cross-linking material in particular at least a material of the group epoxy resin, ethyl vinyl acetate, cross-linked polymethane, polysilicon, polyorganosiloxane, cross-linked polyacrylate.

If an ionomer is used as the first polymer material, the invention provides for the fact that this is formed by partial neutralization of an ethylene-methacrylic acid copolymer or an ethylene acrylic acid copolymer with an inorganic base exhibiting cations of sodium or zinc.

In particular, it is proposed that the front-side running first layer has a specific resistance rho₁ with ρi>5×10¹⁶ Ωcm, measured at a temperature of 25° C. This specific resistance prevails immediately after the production of the solar cell module and includes a period up to 1 week after the production. In particular, the specific resistance ρi with the earlier mentioned secondary conditions of temperature and time amounts to 5×10¹⁶ Ωcm to 1×10¹⁹ Ωcm.

If the storage module G₁ of the first layer is greater than 8×10 Pa, measured at 25° C. and 1 Hz after processing into the solar cell module, the invention provides further that the storage module G₁ of the rear-side, thus the second layer, is smaller than 8×10⁶ Pa in same secondary conditions.

In particular, the storage module G₁ (storage module of the first layer) is 8×10⁶ Pa<G₁<8×10⁷ Pa and the storage module G₂ (storage module of the second layer) 8×10⁵ Pa<G₂′<8×10⁶ Pa, measured with due consideration of the above mentioned parameters.

Preferably, the first or front-side layer consists of an ionomer, which is formed by partial neutralization of ethylene methacrylic acid copolymers or ethylene acrylic acid copolymers with an inorganic base exhibiting cations of sodium or zinc, and the second layer from ethyl vinyl acetate (EVA) or from a polyethylene polypropylene copolymer.

A further preferred material combination is a PE-PP-copolymer as the first layer and EVA as second layer.

An ionomer of earlier mentioned characterization, thus such a one, which is formed by partial neutralization of an ethylene methacrylic acid co-polymer or an ethylene acrylic acid co-polymer with an inorganic base having cations of sodium or zinc, has a storage module G′ of 3×10⁷ Pa. The EVA-material has a storage module G′ of 3×10⁶ Pa for the formation of the second layer. When using PE-PP-copolymer as the first layer, the storage module G′ amounts to 6 to 8×10⁶ Pa.

The specific resistance of EVA lies between 1×10¹⁴ Ωcm and 1×10¹⁵ Ωcm. The specific resistance of PE-PP-co-polymer is 5×10¹⁶ Ωcm. With regard to the ionomer characterized earlier, a specific resistance between 5×10¹⁷ Ωcm and 5×10¹⁸ Ωcm results in. Silicone has a specific resistance of 5×10¹⁶ Ωcm.

Further details, advantages and features of the invention result in not only from the claims, which are deduced from the characteristic features—for themselves and/or in combination, but also from the following description of a preferred embodiment given in the drawing.

### DESCRIPTION OF THE DRAWING

In the only FIGURE, in principle, a schematic drawing of a solar cell module is shown.

### BRIEF DESCRIPTION OF THE PREFERRED EMBODIMENTS

Referring to the FIGURE, the solar cell module consists of a front-side stable transparent cover 1, with which it concerns a soda lime glass e.g. a thickness between 3 mm and 5 mm, in particular within the range of 4 mm. A first layer 2 joins the cover 1, which can consist of a thermoplastic material of the Group ionomer, polymethyl methacrylate, PP, polycarbonate, polyethylene terephthalate, polyolefin with ionic and covalent bonds, Polyvinyl butyral, thermoplastic polyurethane, polypropylene, polyethylene, polystyrene, siloxane or copolymers of these or combinations of suitable materials. In particular, a PE-PP-copolymer is to be mentioned, which has UV-blocker.

The thickness of the first layer 2 can lie in the range between 0.3 and 0.7 mm, in particular within the range of 0.5 mm.

The first layer runs independent of this directly on the radiation-inclined front-side of the solar cells.

The first layer 2 covers the interconnected solar cells 3, which are covered on the rear-side by a second layer 4, which can consist of polysilicon, plyorganosiloxane, cross-linked polyacrylate or combinations of suitable materials of a cross-linking material, in particular a material of the Group epoxy resin, ethyl vinyl acetate, cross-linked polymethane. Preferably EVA is to be mentioned. The thickness of the second layer 4 can correspond to that of the first layer 2.

Rear-side the second layer is covered by a polyvinyl fluoride film, whose thickness can be in the range of 1 and 2 mm.

For manufacturing a module, first on the front-side cover 1, the first layer 2 is applied in the form of a film, on which then the solar cells are presented for formation of a matrix and interconnected or interconnected solar cells are positioned on the foil forming the first layer 2. Thus, for formation of the solar cell rear-side running second layer 4, a film is applied, which is then covered by the rear-side cover 5. Subsequently, lamination to the solar cell module takes place at a temperature in particular above 120° C.

The cross-linking material of the second layer 4, in particular ethyl vinyl acetate, interlaces at the used lamination temperature and prevents thus a slipping of solar cells forming the Matrix during the lamination process.

Since the front-side, thus the foil forming the first layer 2 consists of a thermoplastic material; this has a low viscosity at the applied lamination temperature.

The storage module G₂′ of EVA-measured at 25° C. and 1 Hz is 3×10⁶ Pa, so that the mechanical shearing stresses in the module unit remains below a critical threshold and the delaminating of the unit is prevented. In contrast, the foil forming the first layer 2 from thermoplastic material exhibits a substantially larger storage module G₁′, which amounts to 9×⁶10 Pa in the use of PE-PP-copolymer as thermoplastic material. Since the suitable foil consisting of the thermoplastic material such as PE-PP-copolymer and the first layer 2 forming foil is used on the front-side of the solar cell matrix, the front-side cove 1 takes a major part of the shearing stress. The shear stress G₂′ of the rear-side or second layer such as EVA-layer strains the solar cell matrix and should therefore possess only one storage module <8×10⁶ Pa.

It is advantageous that the specific resistance of the first layer 2 is greater than that of the second layer 4, so that the potential-induced degradation harmful for crystalline silicon solar cells is prevented.

When using PP-PE-co-polymer material for the first layer, the specific resistance 5×10 Ωcm¹⁶ is measured at 25° C., immediately after the processing of the solar cell module.

Alternatively, the first layer can be manufacture from a. 0.5 mm thick foil of a translucent ionomer, which is formed by partial neutralization of an ethyl methacrylic acid co-polymer or an ethylene acrylic acid copolymer with an organic base, which exhibits cations of sodium or zinc.

The specific resistance ρ₂ of the suitable formed layer 2 is greater than 1×10¹⁷ Ωcm and the storage module G₂′ greater than 2×10⁷ Pa, so that the same advantages occur as in the use of PE-PP-copolymer as material for the first layer 2.

The rear-side or second layer 4 should consist again of ethyl vinyl acetate. The same materials can also be used, as in the first example, for front- and rear-side covers 1, 5.

What is claimed is:

1. Solar cell module comprising electrically interconnected solar cells with front and backs, a transparent first layer running along the front sides, which is covered on the front laterally by a transparent cover, as well as a second layer running along the backsides, which is covered at the back by a second cover, wherein the first layer consists of a first polymer material and the second layer consists of a second polymer material deviating from the first polymer material and the fact that specific resistance is larger p₁ of the first material is greater than specific resistance p2 of the second material, and storage module G₁ of the first layer is greater than the storage module G₂ of the second layer.

2. Solar cell module according to claim 1, wherein the first polymer material is a thermoplastic material, in particular at least a material from the group of ionomer, polymethyl methacrylate, polyamide, polycarbonate, polyethylene terephthalate, polyolefin with ionic and covalent compounds, polyvinyl butyral, thermoplastic polyurethane, polypropylene, polyethylene, polystyrene, Sloane or co-polymers of these or combinations thereof.

3. Solar cell module according to claim 2, wherein the second polymer material is a cross-linking material, in particular at least a material from the group epoxy resin, ethyl vinyl acetate, cross-linked polymethane, polysilicon, polyorgano-siloxane, cross-linked polyacrylate or combinations of these.

4. Solar cell module according to claim 2, wherein the ionomer is formed as the first polymer material by partial neutralization of an ethylene-methacryl acid co-polymer or an ethylene-acryl acid copolymer with an exhibiting inorganic base having cations of sodium or zinc.

5. Solar cell module according to claim 1, wherein the specific resistance p₁ of the first layer amounts to 5×10¹⁶ Ωcm≦p₁≦5×10¹⁹ Ωcm, measured at 25° C.

6. Solar cell module according to claim 1, wherein the storage module G₁ of the first layer amounts to G₁>8×10⁶ Pa and/or that the storage module G₂ of the second layer amounts to G₂<8×10⁶ Pa, measured in each case, at 25° C. and 1 Hz.

7. Solar cell module according to claim 1, wherein the first layer comprises of a PE-PP-co-polymer or an ionomer and the second layer of ethyl vinyl acetate (EVA).

8. Solar cell module according to claim 1, wherein the second layer consists of ethyl vinyl acetate (EVA) or a polyolefin.

9. Solar cell module according to claim 1, wherein the first layer comprises of a PE-PP-co-polymer and the second layer of ethyl vinyl acetate (EVA).

10. Solar cell module according to claim 1, wherein the second polymer material is a cross-linking material, in particular at least a material from the group epoxy resin, ethyl vinyl acetate, cross-linked polymethane, polysilicon, polyorgano-siloxane, cross-linked polyacrylate or combinations of these.
